(19) United States
(12) Patent Application Publication
(10) Pub. No.: US 2011/0298041 A1
(43) Pub. Date: Dec. 8, 2011

(54) SINGLE-GATE FINFET AND FABRICATION METHOD THEREOF

(76) Inventor: Shing-Hwa Renn, Taipei City (TW)

(21) Appl. No.: 12/987,153

(22) Filed: Jan. 9, 2011

(30) Foreign Application Priority Data
Jun. 2, 2010 (EP) 10005773.6

(51) Int. Cl. H01L 29/66

(52) U.S. Cl. 257/330; 257/E29.166

(57) ABSTRACT

A single-gate FinFET structure includes an active fin structure having two enlarged head portions and two respective tapered neck portions that connect the enlarged head portions with an underlying ultra-thin body. Two source/drain regions are doped in the two enlarged head portions respectively. An insulation region is interposed between the two source/drain regions. A trench isolation structure is disposed at one side of the tuning fork-shaped fin structure. A single-sided sidewall gate electrode is disposed on a vertical sidewall of the active fin structure opposite to the trench isolation structure.

### BACKGROUND OF THE INVENTION

1. Field of the Invention

The present invention relates to a single-gate fin field-effect-transistor (FinFET) with an ultra-thin body (UTB).

2. Description of the Prior Art

As known in the art, dynamic random access memory (DRAM) is a type of random access memory that stores each bit of data in a separate capacitor within an integrated circuit. Typically, DRAM is arranged in a square array of one capacitor and transistor per cell. The transistor, which acts as switching device, comprises a gate and a silicon channel region underneath the gate. The silicon channel region is located between a pair of source/drain regions in a semiconductor substrate and the gate is configured to electrically connect the source/drain regions to one another through the silicon channel region.

A vertical double-gate fin field-effect-transistor (FinFET) has been developed for the next-generation 4F² DRAM cell (F stands for minimum lithographic feature width). However, difficulties are frequently encountered in attempting to produce the vast arrays of vertical double-gate FinFET devices desired for semiconductor DRAM applications while maintaining suitable performance characteristics of the devices. For example, recently DRAM manufacturers face a tremendous challenge on shrinking the memory cell area as the word line spacing, i.e., the spacing between two adjacent word lines, continues to shrink. The shrinking spacing between two closely arranged word lines leads to undesirable electrical coupling effect for high-speed DRAM applications. Another drawback of the prior art transistor structure is insufficient source/drain contact landing area.

In light of the above, there is a strong need in this industry to provide a novel FinFET structure and the fabrication process therefore to avoid the aforesaid problems.

### SUMMARY OF THE INVENTION

The present invention aims at resolving or eliminating the electrical coupling effect of the advanced DRAM device, which stems from the continuing scaling of the word line spacing and other shrinking rules of the DRAM device.

As will be seen more clearly from the detailed description below, the claimed single-gate FinFET structure comprises an active fin structure comprising two enlarged head portions and a tapered neck portion that connects the enlarged head portions with an underlying ultra-thin body; two source/drain regions doped in the two enlarged head portions respectively; an insulation region interposed between the two source/drain regions; a trench isolation structure disposed at one side of the tuning fork-shaped fin structure; and a single-sided sidewall gate electrode disposed on a vertical sidewall of the active fin structure opposite to the trench isolation structure.

According to one aspect of the invention, a single-gate fin field-effect-transistor includes an active fin structure comprising two head portions, each connected to a respective tapered neck portion that connects the head portions with an underlying body between the two neck portions and having an ultra-thin channel region, the two head portions each having an enlarged surface area with respect to the respective tapered neck portion; a trench isolation structure disposed at one side of the active fin structure; and a sidewall gate electrode disposed on a single side of a vertical sidewall of the active fin structure that is opposite to the trench isolation structure.

According to another aspect of the invention, a single-gate fin field-effect-transistor includes an active fin structure comprising two head portions, each connected to a respective tapered neck portion that connects the head portions with an underlying body between the two neck portions and having an ultra-thin channel region, the two head portions each having an enlarged contact area with respect to the respective tapered neck portion, and each having a width that is greater than that of the body; a trench isolation structure disposed at one side of the active fin structure; and a sidewall gate electrode disposed on a single side of a vertical sidewall of the active fin structure that is opposite to the trench isolation structure.

According to still another aspect of the invention, a DRAM array includes an array of fin field-effect-transistors comprising two mirror symmetrical single-gate fin field-effect-transistors arranged in two adjacent columns and in the same row of the DRAM array, wherein each of the single-gate fin field-effect-transistors is fabricated in an active fin structure comprising two enlarged head portions and a tapered neck portion that connects the enlarged head portions with an underlying ultra-thin body; a trench isolation structure disposed at one side of the active fin structure; and a single-sided sidewall gate electrode disposed on a vertical sidewall of the active fin structure opposite to the trench isolation structure.

According to yet another aspect of the invention, an array of fin field-effect-transistors includes two mirror symmetrical single-gate fin field-effect-transistors arranged in two adjacent columns and in the same row of the array, each of the two mirror symmetrical single-gate fin field-effect-transistors comprising: an active fin structure comprising an underlying body including a channel region of the array; two head portions above the underlying body, where source/drain regions are formed, wherein the two head portions are enlarged compared to the underlying body; and a tapered neck portion that connects the head portions with the underlying body; a bottle-shaped trench isolation structure disposed between the head portions, the tapered neck portion and the underlying body of two of the active fin structures; and single-sided sidewall gate electrodes disposed on a vertical sidewall of each active fin structure opposite to the trench isolation structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic layout diagram showing a portion of a DRAM array in accordance with one preferred embodiment of this invention;

FIG. 2 shows schematic, cross-sectional views of the single-gate FinFETs of the invention, which are taken along line AA′ and line BB′ of FIG. 1 respectively;

FIG. 3 is a schematic, perspective view of the single-gate FinFETs of the invention, wherein some gap-fill dielectrics in the isolation regions are omitted for the sake of clarity; and

FIGS. 4-12 are schematic diagrams showing the process of fabricating the single-gate FinFET in accordance with one embodiment of the present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

In the following description, numerous specific details are given to provide a thorough understanding of the invention. However, it will be apparent to one skilled in the art that the invention may be practiced without these specific details. In order to avoid obscuring the present invention, some well-known system configurations and process steps are not disclosed in detail.

Likewise, the drawings showing embodiments of the apparatus are semi-diagrammatic and not to scale and, particularly, some of the dimensions are for the clarity of presentation and are shown exaggerated in the figures. Also, in which multiple embodiments are disclosed and described having some features in common, for clarity and ease of illustration and description thereof, like or similar features will ordinarily be described with like reference numerals.

The term “horizontal” as used herein is defined as a plane parallel to the conventional major plane or primary surface of the semiconductor substrate, regardless of its orientation. The term “vertical” refers to a direction perpendicular to the horizontal as just defined. Terms, such as “on”, “above”, “below”, “bottom”, “top”, “side” (as in “sidewall”), “higher”, “lower”, “over”, and “under”, are defined with respect to the horizontal plane.

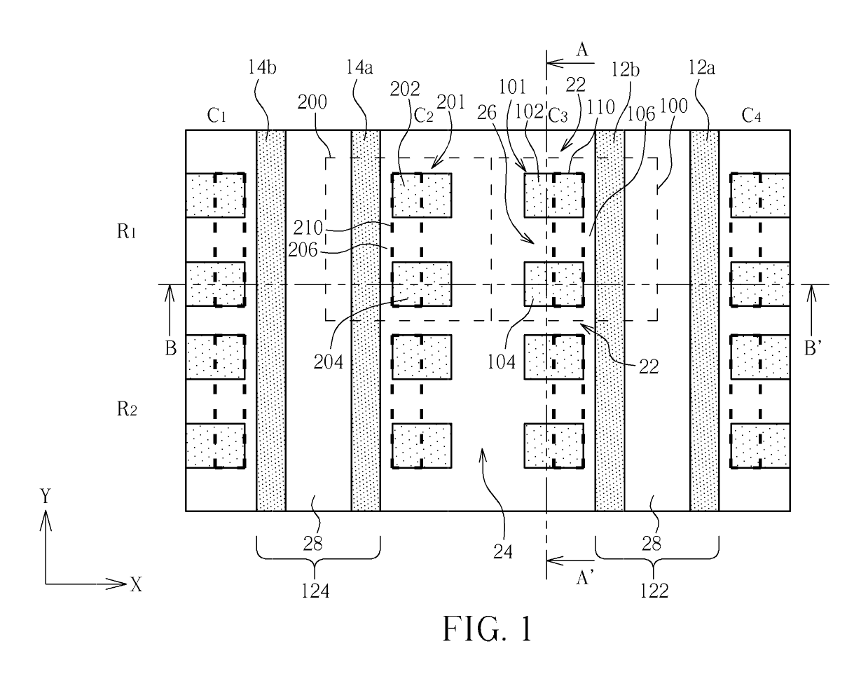

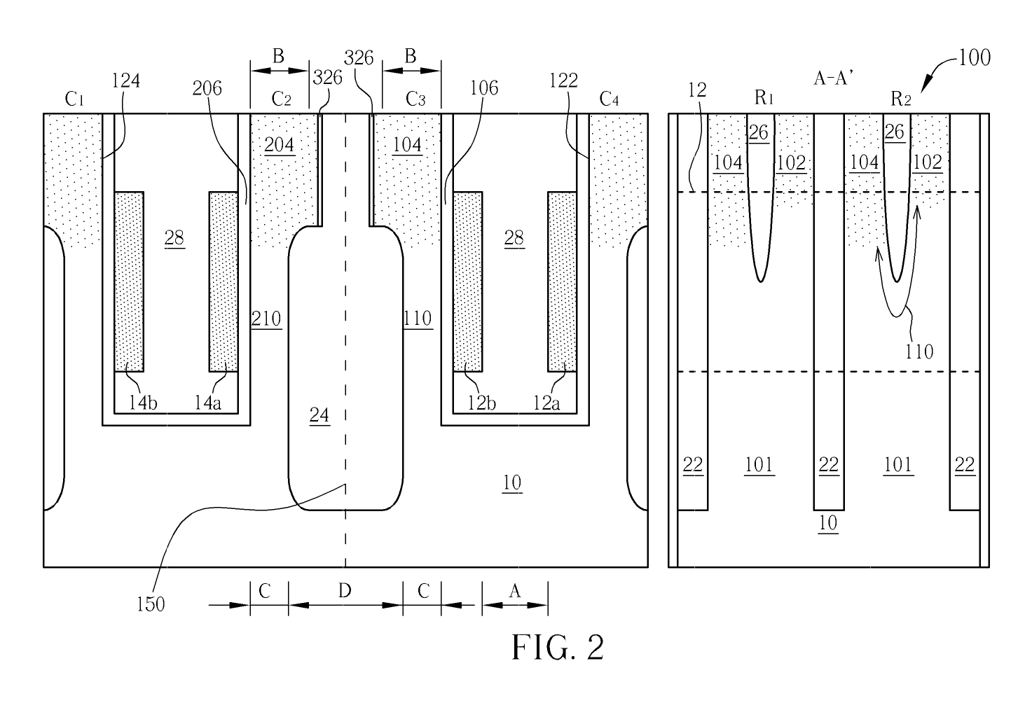

FIG. 1 is a schematic layout diagram showing a portion of a DRAM array 1 in accordance with one preferred embodiment of this invention. FIG. 2 shows schematic, cross-sectional views of the single-gate FinFETs and single-gate FinFET array of the invention, which are taken along line AA′ (reference y-axis direction) and line BB′ (reference x-axis direction) of FIG. 1 respectively. In FIG. 1, the demonstrated portion of the DRAM array comprises eight single-gate FinFETs arranged in four columns (C1˜C4) and two rows (R1 and R2), including single-gate FinFET 100 and single-gate FinFET 200, for example, which are arranged in the same row (R1) and in two adjacent columns (C2 and C3 respectively).

The single-gate FinFETs 100 and 200, which are formed in the active fin structures 101 and 201, are indicated by the dotted line and are arranged in close proximity to each other. According to the embodiment of the invention, each single-gate FinFET and a corresponding capacitor element (not shown) can be configured as a DRAM cell with a device area of 4f2 or even smaller. Sidewall word lines 12a, 12b, 14a and 14b, which extend along the reference y-axis, are provided next to each column of transistors.

The sidewall word lines 12a and 12b are embedded in a line-shaped trench 122 and are disposed on two opposite sidewalls of the line shaped trench 122, wherein the sidewall word line 12a that passes the active fin structure 101 acts as a single-sided sidewall gate electrode of the single-gate FinFET 100 and the sidewall word line 14a that passes the active fin structure 201 acts as a single-sided sidewall gate electrode of the single-gate FinFET 200. The line-shaped trenches 122 and 124 may be filled with insulating layer 28 such as silicon oxide or the like. The term “single-sided” refers to that the gate electrode 12a is only formed on one side of the transistor.

By way of example, the single-gate FinFET 100, which is fabricated in the active fin structure 101, comprises two source/drain regions 102 and 104 spaced apart from each other, a recessed, U-shaped channel 110 under the two source/drain regions 102 and 104, the word line 12a that acts as a gate electrode, and a gate dielectric layer 106 between the U-shaped channel 110 and the word line 12a. Likewise, the single-gate FinFET 200, which is fabricated in the active fin structure 201, comprises two source/drain regions 202 and 204 spaced apart from each other, a recessed, U-shaped channel 210 under the two source/drain regions 202 and 204, the word line 14a that acts as a gate electrode, and a gate dielectric layer 206 between the U-shaped channel 210 and the word line 14a.

According to the embodiment of the invention, the single-gate FinFET 100 and the single-gate FinFET 200 are mirror symmetrical to each other with respect to a central plane 150. As can be seen in AA′ cross-section of FIG. 2, the active fin structure 101 is a tuning fork-shaped silicon island with an insulation region 26 interposed between the two source/drain regions 102 and 104. The insulation region 26 is located above the U-shaped channel 210 that is between the two source/drain regions 102 and 104. Basically, the width and depth of the recess formed between the source/drain regions 102 and 104 substantially determine the channel length of the U-shaped channel 110. The single-gate FinFET 100 is electrically isolated from the single-gate FinFET 200 by a bottle-shaped trench isolation structure 24 that extends along the reference y-axis direction. The bottle-shaped trench isolation structure 24 has a widened lower portion that is capable of reducing cross talk between adjacent transistors or DRAM cells. The lower portion of the bottle-shaped trench isolation structure 24 is widened in the row direction, namely reference x-axis direction, of the array.

As seen in FIG. 1 and FIG. 2, the insulation region 26 extends along the reference x-axis direction and the single-sided sidewall gate electrode 12a, 14a extends along the reference y-axis direction that is perpendicular to the reference x-axis direction. The insulation region 26 is in contact with the single-sided sidewall gate electrode 12a, 14a. In one aspect, the insulation region 26 extends along the reference x-axis direction and the trench isolation structure 24 extends along reference y-axis direction that is perpendicular to the reference x-axis direction. The insulation region 26 is in contact with the trench isolation structure 24.

For device isolation, a plurality of line-shaped shallow trench isolation (STI) regions 22 are provided and embedded in the substrate 10 to provide electrical isolation between two adjacent rows of devices. As can be seen in FIG. 1, each of the line-shaped STI regions 22 extends along the reference x-axis direction and intersects with the sidewall word lines 12a, 12b, 14a and 14b.

As shown in FIG. 1 and FIG. 2, at least four critical feature rules or parameters are defined herein. These critical feature rules or parameters includes (1) rule A: the spacing between two adjacent sidewall word lines embedded in the same trench; (2) rule B: the dimension of the source/drain contact area in the reference x-axis direction; (3) rule C: the thickness of the channel region of the transistor; and (4) rule D: the width of the bottle-shaped trench isolation structure between two mirror symmetrical transistors. It is desirable to make parameters A, B and D as large as possible, while minimizing C, because an increased A between two adjacent sidewall word lines and increased width of the bottle-shaped trench isolation structure can reduce cross talk, and increased B can provide enlarged contact landing area, which facilitate the miniaturization of the DRAM cell devices.

The present invention provides ultra-thin body by minimizing the rule C, and the concomitant benefits include: (1) shorter channel resulting in good short-channel behavior and higher driving current; and (2) channel volume inversion resulting in higher mobility (driving current). According to the embodiment of the invention, the rule B is greater than the rule C. In other words, the present invention single-gate FinFET structure provides increased contact landing area while maintaining an ultra-thin body in the channel region.

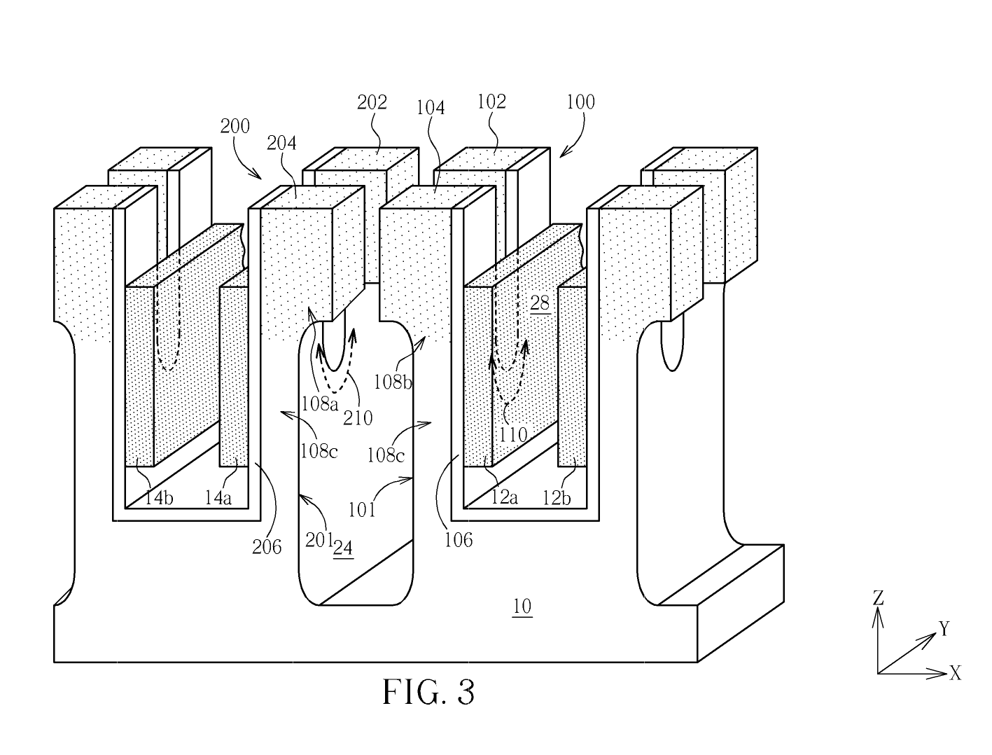

FIG. 3 is a schematic, perspective view of the single-gate FinFETs 100 and 200 of FIG. 1, wherein gap-fill dielectrics in some isolation regions are omitted for the sake of clarity. As shown in FIG. 3, according to the embodiment of the invention, the active fin structure 101, for example, comprises two enlarged prong-like head portions 108a where the source/drain regions 102 and 104 are formed, and a tapered neck portion 108b that connects the enlarged head portions with the ultra-thin body 108c wherein the U-shaped channel region 110 is formed under the source/drain regions 102 and 104. In one aspect, each of the two fin structures 101 and 201, for example, is analogous to a tuning-fork with two widened prong tips and the two widened prong tips substantially constitute the source/drain regions 102 and 104.

With reference to FIG. 3, the term “enlarged” and the term “ultra-thin” compare the dimensions of the head portions 108a and the underlying body 108c to each other to thereby outlining that the head portion 108a is larger than the underlying body 108c. The head portion 108a is “enlarged” compared to the underlying body 108c. The tapered neck portion 108b connecting the head portion 108a and the body 108c becomes larger in its cross section when moving from the underlying body 108c up to the head portion 108a. The term “ultra-thin” refers to thickness of channel region of transistor. The term “enlarged” means that the head portion 108a has an enlarged surface contact area with respect to the tapered neck portion 108b. FIG. 3 also shows an array of single-gate fin field effect transistors with at least two mirror symmetrical single-gate fin field effect transistors and the trench isolation structure 24 therebetween. The single-gate Fin FET array of the present invention provides increased contact landing area while maintaining an ultra-thin body in the channel region.

To sum up, the present invention provides a FinFET structure and an DRAM array thereof having two heads (108a) facing each other, both heads going into a neck region (108b) that is thinner than the heads, and then going into a body region (108c), which has an isolation trench (24) therein. The body region can be U-shaped or V-shaped. There is a single-sided gate (12a, 14a) on the sidewall that is opposite to the isolation trench region. The heads are doped, meaning their surface area is increased as compared to the prior art.

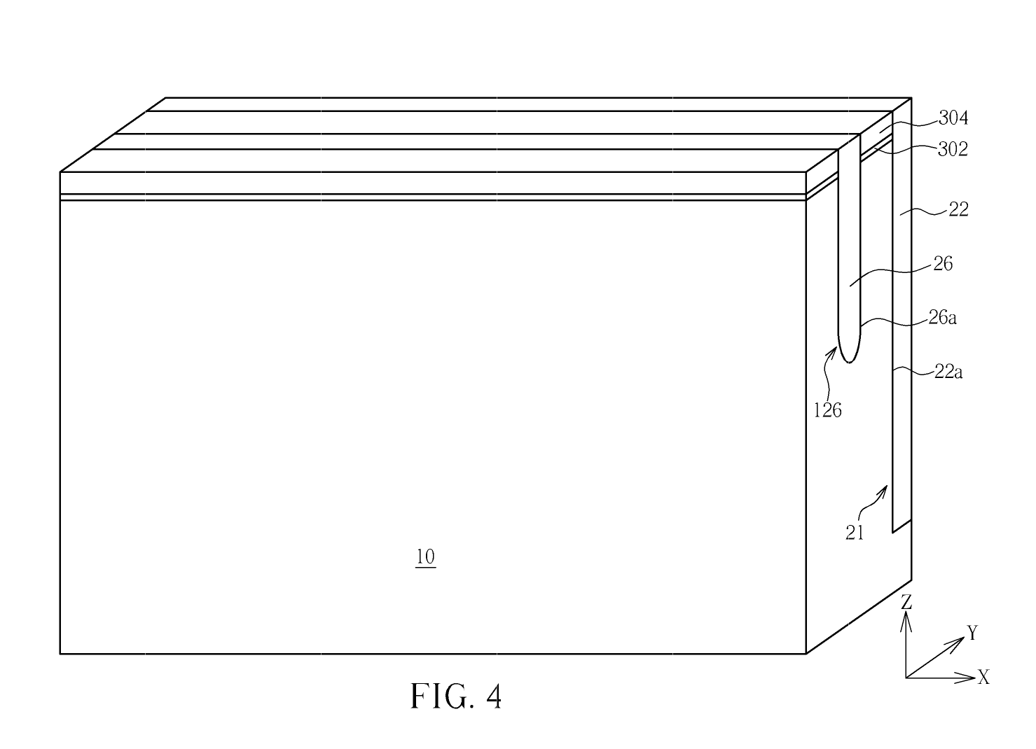

FIGS. 4-12 are schematic diagrams showing the process of fabricating the single-gate FinFET in accordance with one embodiment of the present invention, wherein like numeral numbers designate like layers, regions or elements.

As shown in FIG. 4, a substrate 10 is provided. The substrate 10 may be a semiconductor substrate including but not limited to silicon substrate, silicon substrate with an epitaxial layer, SiGe substrate, silicon-on-insulator (SOI) substrate, gallium arsenide (GaAs) substrate, gallium arsenide-phosphide (GaAsP) substrate, indium phosphide (InP) substrate, gallium aluminum arsenic (GaAlAs) substrate, or indium gallium phosphide (InGaP) substrate. A pad oxide layer 302 and a pad nitride layer 304 may be formed over the primary surface of the substrate 10. A STI process is then carried out to form line-shaped STI regions 22 embedded in the substrate 10. The line-shaped STI regions 22 provide electrical isolation between two adjacent rows of devices.

According to the embodiment of the invention, each of the line-shaped STI regions 22 extends along the reference x-axis direction. The line-shaped STI regions 22 may be formed by spin-on-dielectric (SOD) gap-fill methods. A lining layer 22a may be formed in the STI trench 21. The lining layer 22a may comprise silicon oxide, silicon nitride or combination thereof. Preferably, the lining layer 22a comprises a silicon oxide layer (not explicitly shown) formed on interior surface of the STI trench 21 and a silicon nitride layer (not explicitly shown) on the silicon oxide layer. The lining layer 22a prevents SOD gap filling material from consuming the substrate 10.

Subsequently, an insulation region 26 is formed in the substrate 10 between two source/drain regions. The insulation region 26 also extends along the reference x-axis direction. Likewise, the insulation region 26 may be formed by SOD gap-fill methods. A lining layer 26a may be formed in the recessed trench 126 for lining the interior surface of the recessed trench 126. The lining layers 22a and 26a can prevent the substrate 10 from silicon consumption during the curing process of the SOD gap filler. Thereafter, the entire surface of the substrate 10 is subjected to polishing process such as chemical mechanical process, and the pad oxide layer 302 and the pad nitride layer 304 are removed.

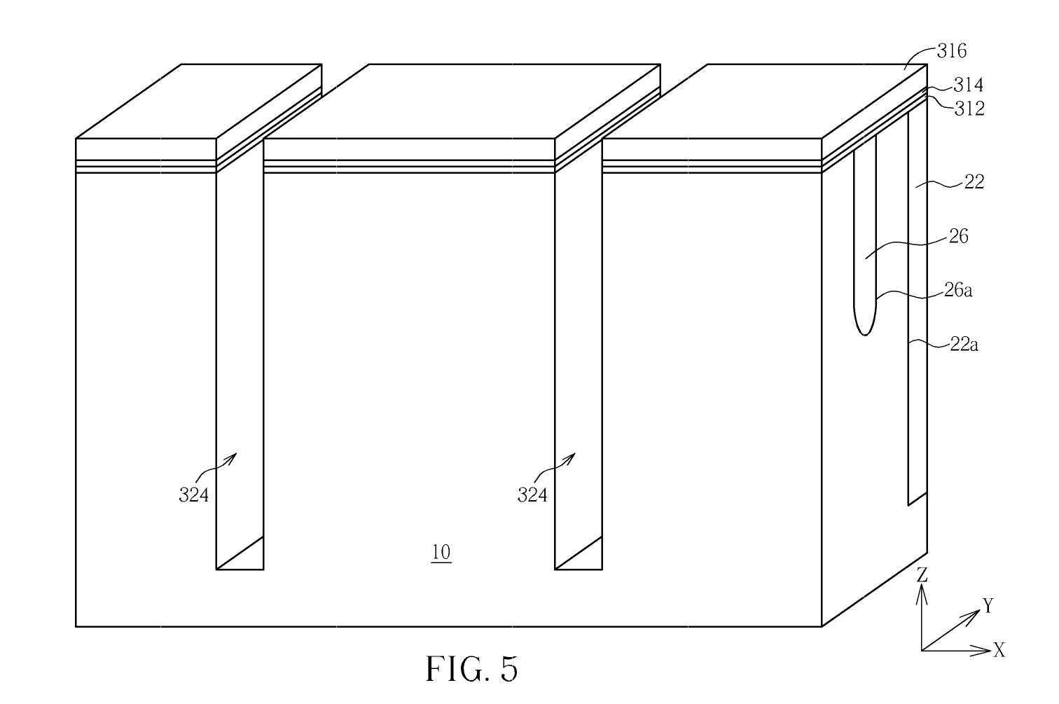

As shown in FIG. 5, a silicon oxide layer 312, a silicon nitride layer 314 and a polysilicon hard mask 316 are formed on the planar surface of the substrate 10 after the removal of the pad oxide layer 302 and the pad nitride layer 304. A lithographic process and dry etching process are carried out to form line-shaped trenches 324 extending along the reference y-axis direction. The line-shaped STI regions 22 and the insulation region 26 are intersected with the line-shaped trenches 324.

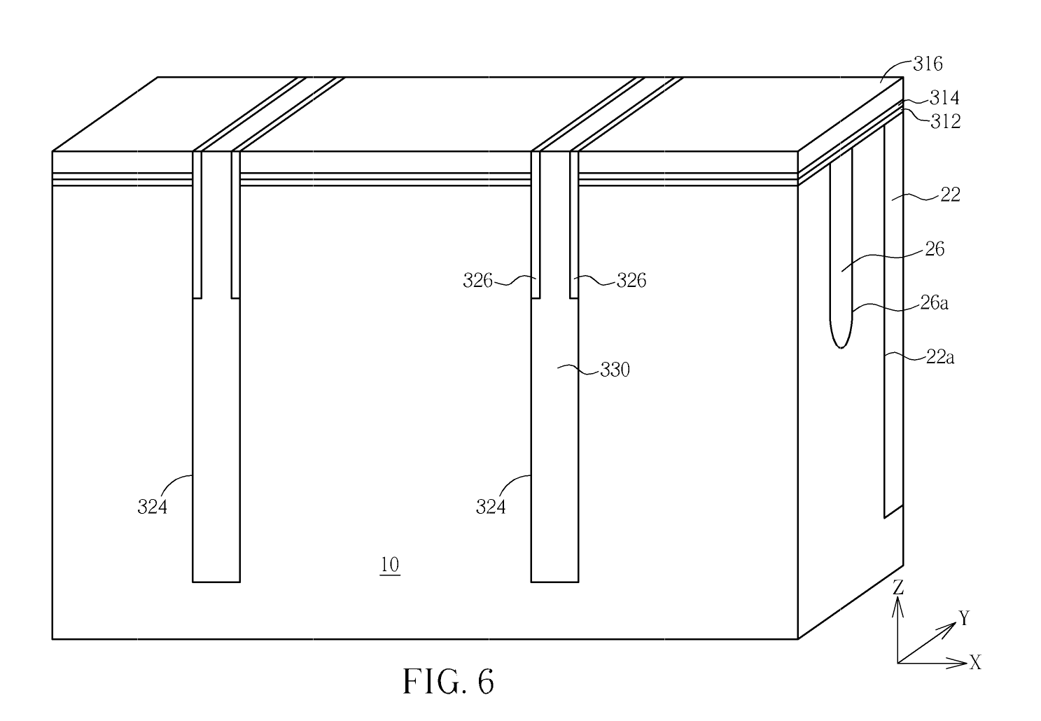

As shown in FIG. 6, a collar protection layer 326 is then formed on the upper portion of the vertical sidewall of the line-shaped trenches 324. The lower portion and bottom surface of the line-shaped trenches 324 are exposed. According to the embodiment of the invention, the collar protection layer 326 may comprise silicon nitride. Subsequently, an SOD gap-filler 330 is coated on the substrate 10 and fills the line-shaped trenches 324. The SOD gap filler 330 may comprise polysilazane precursor but not limited thereto.

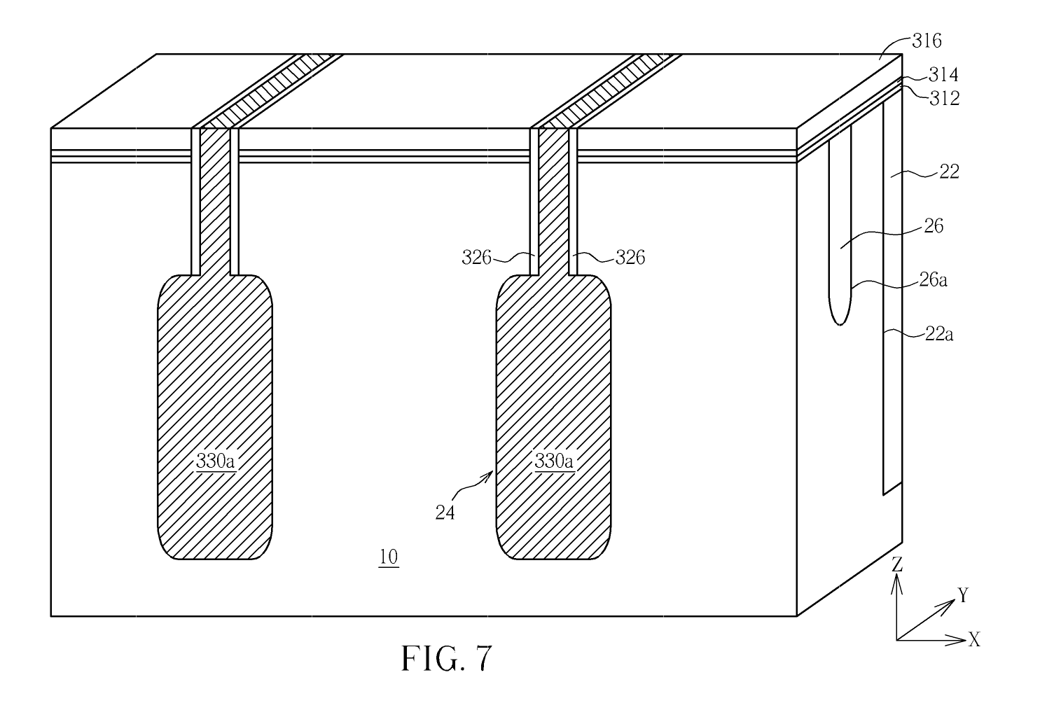

As shown in FIG. 7, a curing process is then carried out to transform the SOD gap filler 330 into silicon oxide gap filler 330a. For example, the curing process may be carried out at high temperatures with the presence of steam. During the curing process, the lower portion and bottom surface of the line-shaped trenches 324 are consumed, while the collar portion of the line-shaped trenches 324 is protected with the collar protection layer 326. At this point, a bottle-shaped trench isolation structure 24 is created. It is understood that the bottle-shaped trench isolation structure 24 may be fabricated with other process steps known in the art, for example, wet etching methods.

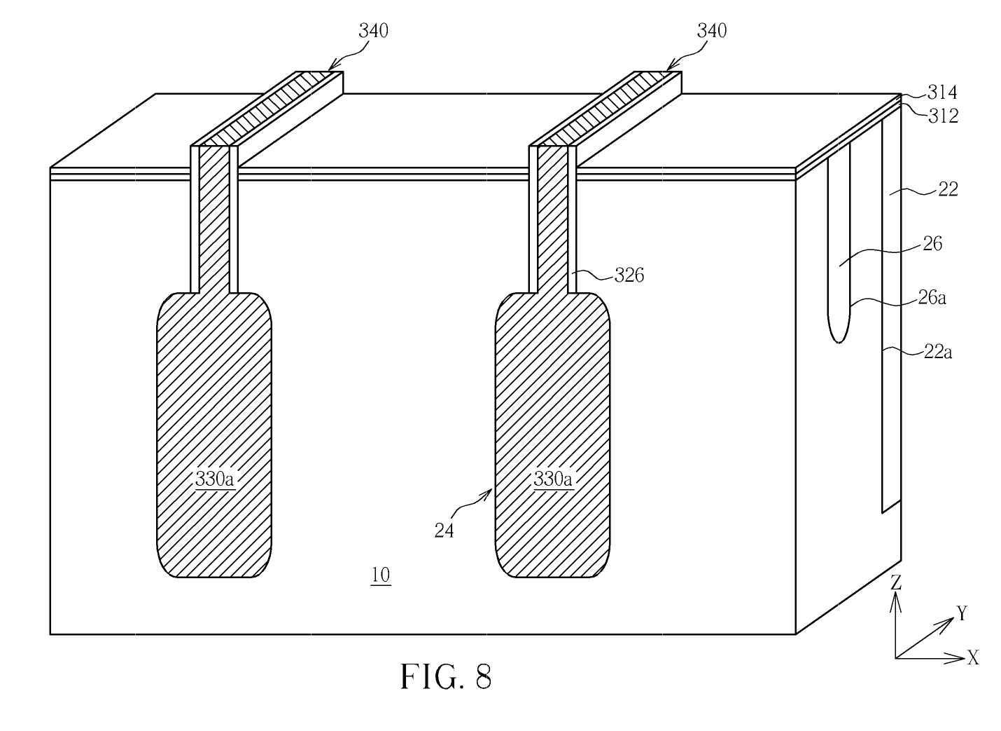

As shown in FIG. 8, after the formation of the bottle-shaped trench isolation structure 24, the polysilicon hard mask 316 is completely removed from the surface of the substrate 10, thereby forming ridges 340 extending along the reference y-axis direction. The two opposite sidewalls of each of the ridges 340 are covered with the collar protection layer 326.

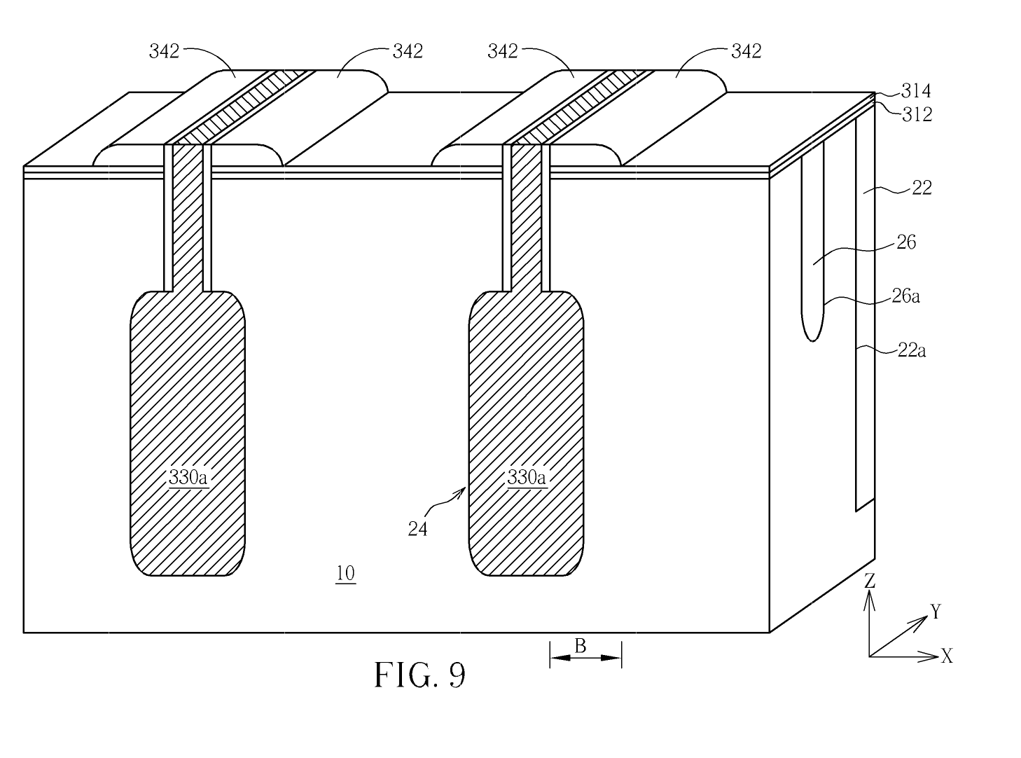

As shown in FIG. 9, subsequently, a spacer material layer (not explicitly shown in this figure) is deposited over the substrate 10 in a blanket fashion. The spacer material layer covers the ridges 340 and the silicon nitride layer 314. Preferably, the spacer material layer comprises silicon oxide, oxynitride or carbide, but not limited thereto. An anisotropic dry etching process is then performed to etch the spacer material layer to thereby form a pair of spacers 342 on two opposite sidewalls of each of the ridges 340.

According to the embodiment of the invention, the spacer 342 has a bottom width that is substantially equal to the rule B. In other words, the lateral thickness (in reference x-axis direction) of the spacer substantially determines the dimension of the source/drain contact landing area as well as the thickness of the underlying ultra-thin body.

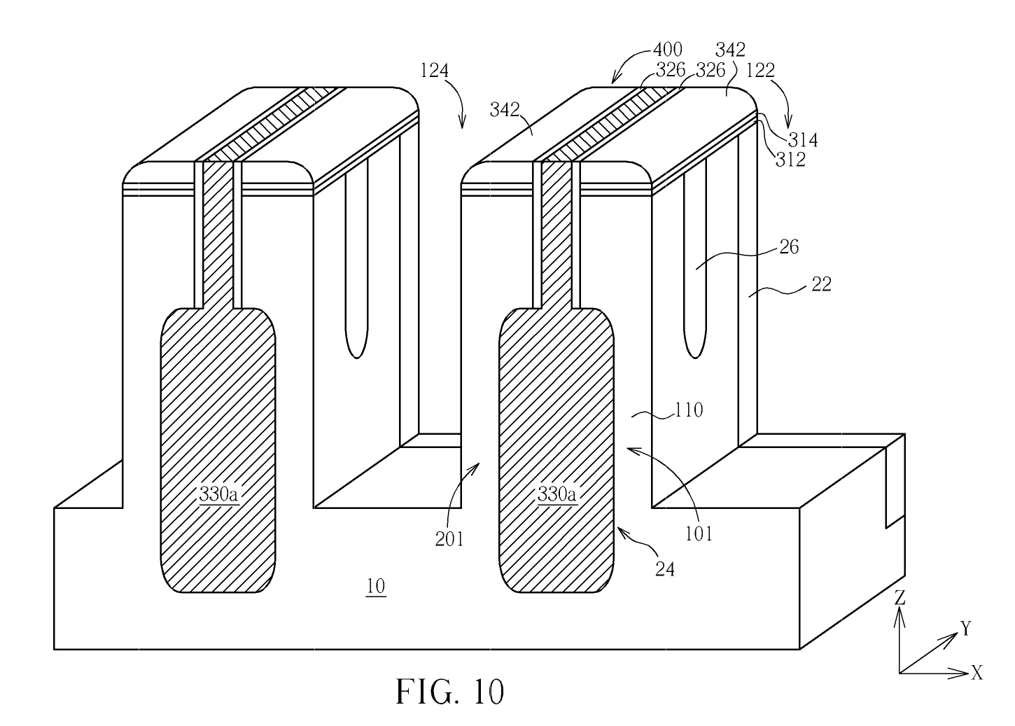

As shown in FIG. 10, using the spacer 342 as an etching hard mask, a self-aligned anisotropic dry etching process is carried out to etch away a portion of the silicon nitride layer 314, the silicon oxide layer 312 and the substrate 10 not covered by the spacer 342, thereby forming a line-shaped protruding structure 400 and line-shaped trenches 122 and 124 on two sides of the line-shaped protruding structure 400, which extend along the reference y-axis direction. The active fin structures 101 and 201 are formed in the line-shaped protruding structure 400. More specifically, the line-shaped protruding structure 400, which extends along the reference y-axis direction, comprises the active fin structures 101 and 201, the silicon oxide gap filler 330a between the active fin structures 101 and 201, the collar protection layer 326, the silicon oxide layer 312, the silicon nitride layer 314, the spacer 342, the insulation region 26 and the line-shaped STI region 22.

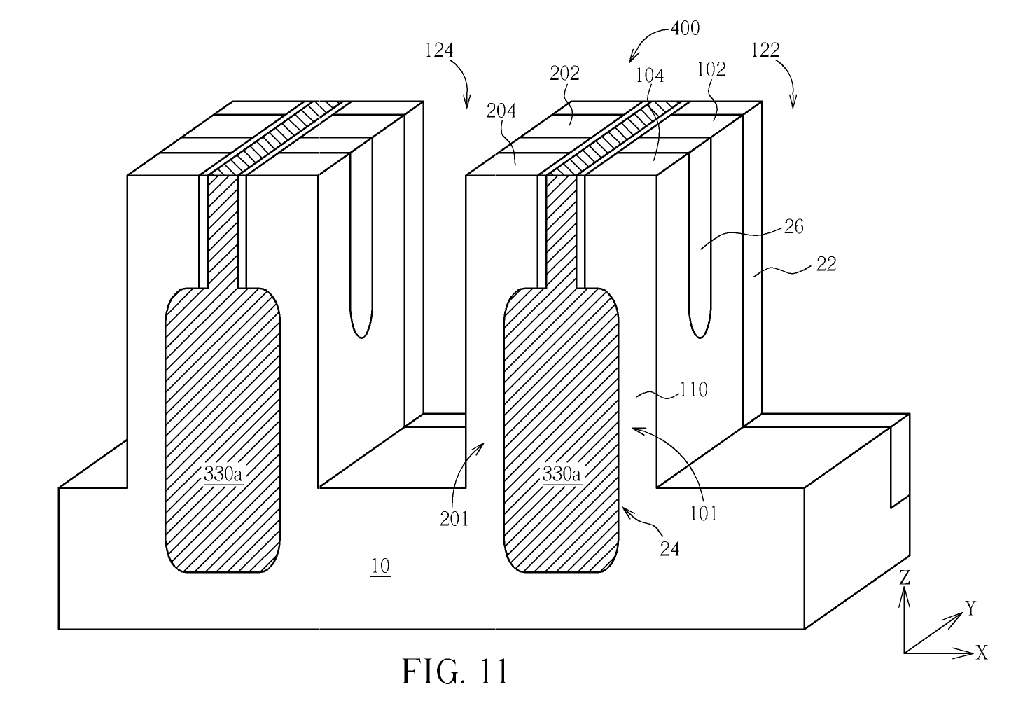

As shown in FIG. 11, after the formation of the line-shaped trenches 122 and 124, the remaining spacer 342 is removed. The silicon nitride layer 314 and the silicon oxide layer 312 are also removed to expose the source/drain landing areas 102, 104, 202 and 204. Preferably, the ridges 340 and an upper portion of the collar protection layer 326 may be removed at this stage.

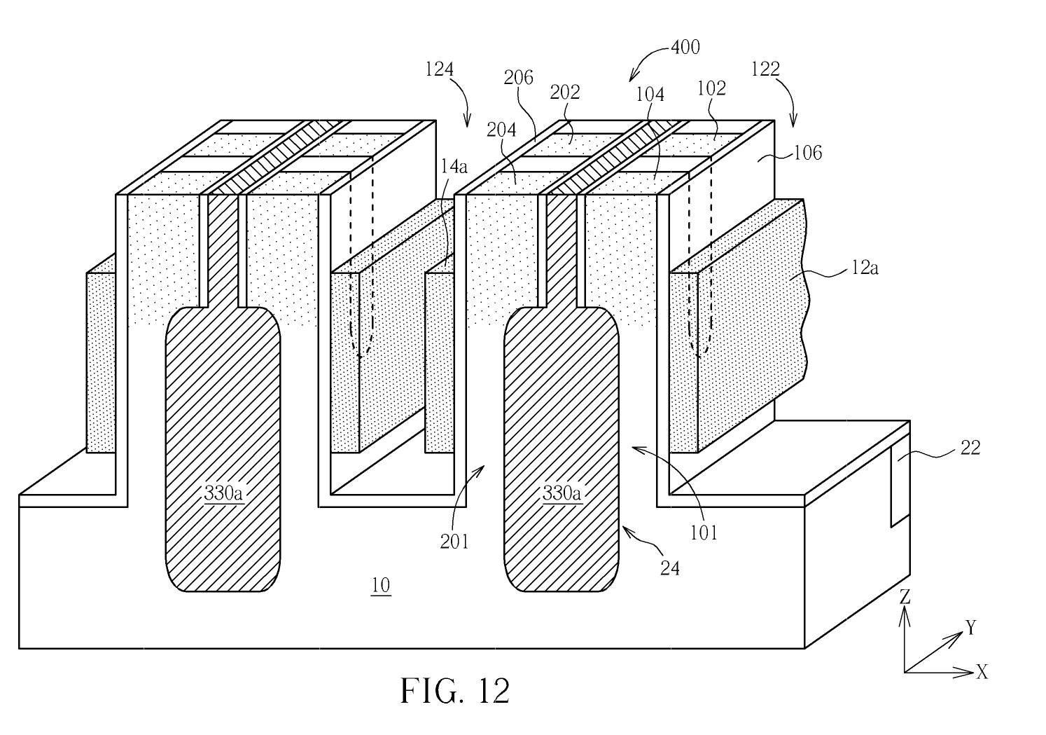

As shown in FIG. 12, a gate dielectric layer 106 and a gate dielectric layer 206 are formed on the two opposite sidewalls of the line-shaped protruding structure 400. The gate dielectric layer 106 and the gate dielectric layer 206 may be formed by in-situ steam growth (ISSG) or any other suitable methods known in the art. Subsequently, sidewall word lines 12a and 14a, for example, are formed on the two opposite sidewalls of the line-shaped protruding structure 400. The sidewall word lines 12a and 14a may be composed of metals, polysilicon or any suitable conductive materials. Thereafter, the line-shaped trenches 122 and 124 may be filled with insulating dielectrics, and then planarized. Finally, source/drain ion implantation are carried out to dope the source/drain landing areas 102, 104, 202 and 204.

Those skilled in the art will readily observe that numerous modifications and alterations of the device and method may be made while retaining the teachings of the invention.

What is claimed is:

1. A single-gate fin field-effect-transistor, comprising:
an active fin structure comprising two enlarged head portions and a tapered neck portion that connects the enlarged head portions with an underlying ultra-thin body;
two source/drain regions doped in the two enlarged head portions respectively;
an insulation region interposed between the two source/drain regions;
a trench isolation structure disposed at one side of the active fin structure; and
a single-sided sidewall gate electrode disposed on a vertical sidewall of the active fin structure opposite to the trench isolation structure.

2. The single-gate fin field-effect-transistor according to claim 1, wherein each of the enlarged head portions has a width that is greater than that of the ultra-thin body.

3. The single-gate fin field-effect-transistor according to claim 1, wherein the trench isolation structure is a bottle-shaped trench isolation structure.

4. The single-gate fin field-effect-transistor according to claim 3, wherein a collar protection layer between an upper portion of the bottle-shaped trench isolation structure and the enlarged head portions of the active fin structure.

5. The single-gate fin field-effect-transistor according to claim 1, wherein a U-shaped channel region in the ultra-thin body between the two source/drain regions.

6. The single-gate fin field-effect-transistor according to claim 1, wherein a gate dielectric layer between the single sidewall gate electrode and the active fin structure.

7. The single-gate fin field-effect-transistor according to claim 1, wherein a lining layer in a recessed trench for lining the insulation region.

8. The single-gate fin field-effect-transistor according to claim 1, wherein the insulation region extends along a first direction and the single-sided sidewall gate electrode extends along a second direction that is perpendicular to the first direction.

9. The single-gate fin field-effect-transistor according to claim 8, wherein the insulation region is in contact with the single-sided sidewall gate electrode.

10. The single-gate fin field-effect-transistor according to claim 1, wherein the insulation region extends along a first direction and the trench isolation structure extends along a second direction that is perpendicular to the first direction.

11. The single-gate fin field-effect-transistor according to claim 10, wherein the insulation region is in contact with the trench isolation structure.

12. The single-gate fin field-effect-transistor according to claim 1, wherein the insulation region is located above a channel region that is between the two source/drain regions.

13. A single-gate fin field-effect-transistor, comprising:
an active fin structure comprising two head portions, each connected to a respective tapered neck portion that connects the head portions with an underlying body between the two neck portions and having an ultra-thin channel region, the two head portions each having an enlarged surface area with respect to the respective tapered neck portion;
a trench isolation structure disposed at one side of the active fin structure; and
a sidewall gate electrode disposed on a single side of a vertical sidewall of the active fin structure that is opposite to the trench isolation structure.

14. A single-gate fin field-effect-transistor, comprising:
an active fin structure comprising two head portions, each connected to a respective tapered neck portion that connects the head portions with an underlying body between the two neck portions and having an ultra-thin channel region, the two head portions each having an enlarged contact area with respect to the respective tapered neck portion, and each having a width that is greater than that of the body;
a trench isolation structure disposed at one side of the active fin structure; and
a sidewall gate electrode disposed on a single side of a vertical sidewall of the active fin structure that is opposite to the trench isolation structure.

15. A DRAM array, comprising:
an array of fin field-effect-transistors comprising two mirror symmetrical single-gate fin field-effect-transistors arranged in two adjacent columns and in the same row of the DRAM array, wherein each of the single-gate fin field-effect-transistors is fabricated in an active fin structure comprising two enlarged head portions and a tapered neck portion that connects the enlarged head portions with an underlying ultra-thin body;
a trench isolation structure disposed at one side of the active fin structure; and
a single-sided sidewall gate electrode disposed on a vertical sidewall of the active fin structure opposite to the trench isolation structure.

16. The DRAM array according to claim 15, wherein the trench isolation structure is a line-shaped isolation structure and extends along a first direction.

17. The DRAM array according to claim 16, wherein the single-sided sidewall gate electrode extends along the first direction.

18. The DRAM array according to claim 16, wherein two source/drain regions are doped in the two enlarged head portions respectively.

19. The DRAM array according to claim 15, wherein each of the enlarged head portions has a width that is greater than that of the ultra-thin body.

20. The s DRAM array according to claim 15, wherein the trench isolation structure is a bottle-shaped trench isolation structure.

21. The DRAM array according to claim 20, wherein a collar protection layer between an upper portion of the bottle-shaped trench isolation structure and the enlarged head portions of the active fin structure.

22. The DRAM array according to claim 15, wherein a gate dielectric layer between the single sidewall gate electrode and the active fin structure.

23. An array of fin field-effect-transistors, comprising:
two mirror symmetrical single-gate fin field-effect-transistors arranged in two adjacent columns and in the same row of the array, each of the two mirror symmetrical single-gate fin field-effect-transistors comprising: an active fin structure comprising an underlying body including a channel region of the array; two head portions above the underlying body, where source/drain regions are formed, wherein the two head portions are enlarged compared to the underlying body; and a tapered neck portion that connects the head portions with the underlying body;
a bottle-shaped trench isolation structure disposed between the head portions, the tapered neck portion and the underlying body of two of the active fin structures; and
single-sided sidewall gate electrodes disposed on a vertical sidewall of each active fin structure opposite to the trench isolation structure.
